(19) United States
(12) Patent Application Publication
(10) Pub. No.: US 2015/0221408 A1
(43) Pub. Date: Aug. 6, 2015

(54) GRAPHENE BASED HYBRID THIN FILMS AND THEIR APPLICATIONS

(71) Applicant: Samsung SDI Co., Ltd., Yongin-si (KR)

(72) Inventors: Kuanping Gong, Fremont, CA (US); Lijie Ci, Jinan (CN)

(21) Appl. No.: 14/600,982

(22) Filed: Jan. 20, 2015

Related U.S. Application Data
(60) Provisional application No. 61/935,783, filed on Feb. 4, 2014.

(51) Int. Cl. H01B 1/04; C23C 16/44; H01B 13/00

(52) U.S. Cl. CPC H01B 1/04; H01B 13/0016; C23C 16/44

(57) ABSTRACT

Graphene-based hybrid films are made by coating electrically conductive nanostructures (such as carbon nanotubes or conductive nanowires) onto a metal substrate, and growing a graphene layer between the nanostructures and the substrate. The nanostructure coating on the substrate yields nucleation sites for the growth of the graphene layer. The process provides hybrid films in which graphene domains are electrically connected by the nanotubes or nanowires. Integral bonds (e.g., chemical bonds) are produced between the nanostructures and the graphene to provide improved electrical conductivity, via contact in excess of van der Waals forces.

### CROSS-REFERENCE TO RELATED APPLICATION

This application claims priority to and the benefit of U.S. Provisional Application Ser. No. 61/935,783, titled GRAPHENE BASED HYBRID THIN FILMS AND THEIR APPLICATIONS, filed on Feb. 4, 2014, the entire content of which is incorporated herein by reference.

### TECHNICAL FIELD

Hybrid nanostructure (e.g., nanotubes and nanowires, etc.) and graphene thin films, and methods of making them are disclosed. The hybrid films can be used in transparent conductive film applications.

### BACKGROUND

Transparent conductive films (TCFs) have been widely used in applications such as touch panel sensors, flat panel displays, solar cells, OLED displays and lighting, etc. Indium tin oxide (ITO) is still a dominant TCF material in those applications. However, due to the increasing cost of ITO source materials and their higher processing costs, cheaper ITO replacement materials are being sought in various applications.

There is a growing interest in developing flexible and stretchable displays, which requires a flexible TCF. ITO is a brittle material, and easily fails when ITO is deposited on a flexible substrate, like polyethylene terephthalate (PET). One dimensional (1D) nanomaterials with high aspect ratios (typically 1000 or greater), such as carbon nanotubes, silver nanowires, and copper nanowires, have been investigated extensively as ITO replacements for TCF applications. These 1D nanomaterials can form random networks on the substrates and provide sufficient electrical conductivity and light transmittance.

Graphene, a two dimensional (2D) continuous carbon film with atomic thickness, has also been investigated as a promising TCF material. Theoretical and experimental results have shown that pristine graphene can be a good transparent conductor material with an intrinsic sheet resistance of about 30Ω/□.

Chemical vapor deposition (CVD) is a promising way to prepare large area graphene on metal substrates such as Ni, Cu, etc. For example, a 30-inch large graphene TCF film has been realized. However, the graphene in a large CVD deposited film is a polycrystalline structure with a domain size of 1 to 100 μm, and the electron scattering at random grain boundaries between graphene domains is a main cause of undesirably high sheet resistance. Research has reported that graphene TCFs can have a theoretical resistivity as low as 30Ω/□ at about 90% visible light transparency (4 layers), and about 125Ω/□ at a transmittance of 97.7% (monolayer graphene). However, these theoretical results have not been proven, and other research has shown that the performance of CVD graphene as a TCF is still not optimal, as shown in the following Table 1:

TABLE 1

| Monolayer | 2-3 layers | 4 layers | 8-10 layers |
|---|---|---|---|
| 2.1 k Ω/▭ | | 350 Ω/▭ @ 90% T | |
| | 350 Ω/▭ | | 280 Ω/▭ @ 80% T |
| 980 Ω/▭ @ 97.6 T | 540 | 350 | |
| | Ω/▭@ 95.3% T | Ω/▭ @ 92.9% T | |
| 125 | | 30 Ω/▭ @ 90% T | |
| Ω/▭ @ 97.7% T | | | |

In order to compete with ITO and other ITO replacement materials, some proposed solutions have included the following techniques:

(1) Multi-layer stacking of graphene: Generally speaking, if each single graphene layer conducts electrons independently, the sheet resistance (Rn) of graphene with n layers will be Rn=R/n, where R is the sheet resistance of a graphene monolayer. However, stacking graphene layers has a tradeoff in the reduction of the light transparency by about 2.3% with each additional monolayer. For a 3 to 4 layer graphene stack, the TCF performance has been reported as a sheet resistance of 350Ω/□ at about 90% light transparency.

(2) Carbon nanotubes (CNTs) overlain on a graphene sheet: Both graphene and CNTs can be good candidates for TCF applications, however, each has their own drawbacks. CVD graphene is a 2D domain-like structure with boundaries of high electrical resistance linked together. CNTs have a network structure with high contact electrical resistance, mainly due to the small contact area between the nanotubes. By simply overlaying CNTs on the surface of a CVD grown graphene layer, a TCF film structure has been created with the following features: a) CNTs crossing the graphene boundaries can increase the electrical conductance between the graphene domains; b) the contact area between the CNTs and graphene is larger than that of the contact between only the nanotubes; and c) the electrical resistance between the CNTs and the graphene layer is reduced. A solution-based method has also been reported, which includes preparing a TCF film using chemically converted graphene and CNTs.

(3) Silver nanowires overlain on a graphene sheet: Using the same idea as that of the CNTs overlain on the graphene sheet, silver nanowires in place of the CNTs may create a TCF with improved electrical conductance due to the silver. A TCF based on a polycrystalline CVD graphene and a sub-percolating silver nanowire network has been proposed. This TCF can have a sheet resistance of <20Ω/□ at >90% light transmittance based on theoretical modeling. However, no experimental data has been demonstrated.

(4) Graphene/metal grids structure: Normal metal materials are opaque when they form a film. However, if they can form thin percolation networks, such as a metal nanowires network (for example silver nanowires, copper nanowires, etc.), or a patterned metal grid, for example, the empty spaces or voids in the network can transmit light. Depending on the area of the void spaces, the metal grids can be transparent and electrically conductive. However, this network structure is not a continuous conducting film, which is required for many applications, such as touch panel sensors. Hybridizing metal grids and CVD graphene films can create continuous TCFs, which have the combined features of high conductivity (from the metal grid), and flexibility and transparency (from the graphene). These TCFs have a reported sheet resistance of about 20Ω/□ at 90% light transmittance.

There are several technical disadvantages in the above-mentioned prior art solutions, some of which include the following:

(1) Multi-layer stacking of graphene: Multilayer CVD graphene stacking is a process with extremely high cost, and is technically not suitable for industrially scalable applications. To transfer 2D CVD graphene from a Cu or Ni substrate, the metallic layer has to be removed by a chemical solution or an electrochemical process. The etching process normally takes hours. For multi-layer stacking, a multi-etching process must be used.

(2) Graphene/CNTs: This method of overlaying nanotubes on a graphene sheet may work for coating small areas with very limited performance. However, the resistance between the nanotubes and the graphene is high due to the simple van der Waals attachment. Additionally, the process is limited for large scale industrial applications.

(3) Graphene/Silver nanowires: This process simply coats silver nanowires on the surface of graphene and forms van der Waals contact between the nanowires and the graphene. However, the resistance between the nanowires and the graphene is still high due to the weak attachment of the silver nanowires on the graphene. Also, the stability of silver nanowires is a big concern.

(4) Graphene/metal grids: The processing cost of lithographic patterning of metal grids is high, and this process is not suitable for large scale roll-to-roll production. Additionally, metal grids could be visible, and therefore are not suitable for some applications. Also, there is only van der Waals contact between the graphene and the metal grid, and the contact resistance is still high.

### SUMMARY

According to embodiments of the present invention, graphene-based hybrid films are made by coating a substrate with nanostructures, such as carbon nanotubes or conductive nanowires, followed by growing a graphene layer between the nanostructures and the substrate. The coating of such nanostructures on the substrate results in certain sections of the nanostructures melting into the substrate, yielding nucleation sites for growing the graphene layer. A carbon source gas is introduced to grow the graphene layer from the nucleation sites between the nanostructures and the substrate.

The graphene is grown in domains on the substrate, where different domains are located around the different nucleation sites on the substrate that are created during coating of the nanostructures. The different graphene domains are electrically connected by the nanostructures that bridge the domains together by virtue of their spanning the different domains. The nanostructures reinforce the graphene film, providing enhanced mechanical properties. The process also yields chemical bonds between the graphene and the nanostructures, which provides enhanced integral contact forces (in excess of van der Waals forces) that result in improved electrical conductivity.

In some embodiments of the present invention, the hybrid TCF product differs from structures of the prior art, which simply bridge graphene boundaries with additional graphene sheets, or with overlain nanotubes or nanowires, and include only van der Waals attractions between the graphene and the bridging material. The hybrid TCF according to embodiments of the present invention includes conductive or semi-conductive nanostructures, such as one dimensional CNTs or nanowires integrally bonded into the graphene film. As mentioned, the resulting hybrid structures have improved mechanical and electrical performance as well as proper light transmittance, as described in more detail below.

In some embodiments of the present invention, a process suitable for large scale industrial applications includes a simplified process involving coating nanotubes and/or nanowires on a metallic substrate, growing graphene on the CNT/nanowire coated substrate via CVD, and transferring the resulting hybrid film to a target substrate (such as, for example, a rigid glass substrate, or a flexible substrate such as polyethylene terephthalate (PET), polyethylene naphthalate (PEN), etc.). The nanotubes/nanowires coating methods can include any traditional high volume printing technique, such as screen printing, slot die coating, spin coating, ink-jet printing, gravure printing, flexo printing, etc. Simply transferring the nanotubes/nanowires films from other substrates to the metallic substrates is also a suitable coating technique.

During the CVD process to grow the graphene, the nanotubes/nanowires are a least partially annealed and partially dissolved into the metallic substrate creating nucleation sites for the growth of the graphene during the process. As the graphene is grown, an integral connection between the nanotubes/nanowires and the newly-deposited graphene is formed. For example, graphene may nucleate and start growing from the nucleation sites created by the partial bonding of the nanotubes/nanowires to the substrate. Because the nanotubes/nanowires and the graphene are more strongly bonded, transferring the resulting hybrid nanotubes/nanowires-graphene film is easier than transferring an all-graphene film.

The structure resulting from the process includes a nanostructure-graphene hybrid film having a metallic substrate, a coating of nanostructures deposited on the substrate and annealed at a graphene deposition temperature to form nucleation sites between the nanostructures and the substrate, and a graphene layer deposited on the substrate and grown in the presence of the nanostructures in domains on the substrate around the nucleation sites to form the hybrid film. The different graphene domains are electrically connected to each other by the nanostructures bridging the graphene domains together in the hybrid film.

In embodiments of the present invention, nanostructures (e.g., CNTs or metal nanowires) are intrinsically bonded into the graphene, and are not bonded to the graphene only by van der Waals contact as in the above-mentioned prior art. The hybrid structures according to embodiments of the present invention have improved electrical properties.

Additionally, according to embodiments of the present invention, graphene films are reinforced by the CNTs/metal nanowires layer, resulting in a hybrid film with improved mechanical properties. In contrast, the prior art graphene films are easily broken during the transfer process, even when used with a thin support layer.

Moreover, the processes according to embodiments of the present invention are lower in cost than prior art graphene multi-stacking processes. As noted above, prior art processes for graphene transfer require metallic substrate etching, which is a costly and time consuming process. Also, the prior art multi-stacking processes requires multi-etching of the metallic substrates, rendering it unsuitable and impractical for large scale industrial applications. In contrast, the processes according to embodiments of the present invention require only one-time etching of the metal substrate, thereby saving a great deal of time and cost.

Furthermore, unlike the processes of the prior art, the processes according to embodiments of the present invention are suitable for large area synthesis and roll-to-roll processing.

### BRIEF DESCRIPTION OF THE DRAWINGS

These and other advantages of the invention will be more fully understood by reference to the following detailed description and the accompanying drawings, in which:

FIG. 1 is a schematic illustration of a graphene-based hybrid transparent film according to embodiments of the present invention;

FIG. 2 is a flow diagram illustrating a process of preparing a hybrid carbon nanotubes-graphene film according to embodiments of the present invention;

FIG. 3 is a flow diagram illustrating a process of preparing a hybrid conductive nanowires-graphene film according to embodiments of the present invention;

FIG. 4 is a photograph depicting a section of a hybrid carbon nanotube-graphene film on Cu foil after graphene deposition; and

FIG. 5 is an optical image of a hybrid double walled carbon nanotubes (DWNTs)-graphene film on a Si wafer (300 nm silicon oxide layer).

### DETAILED DESCRIPTION

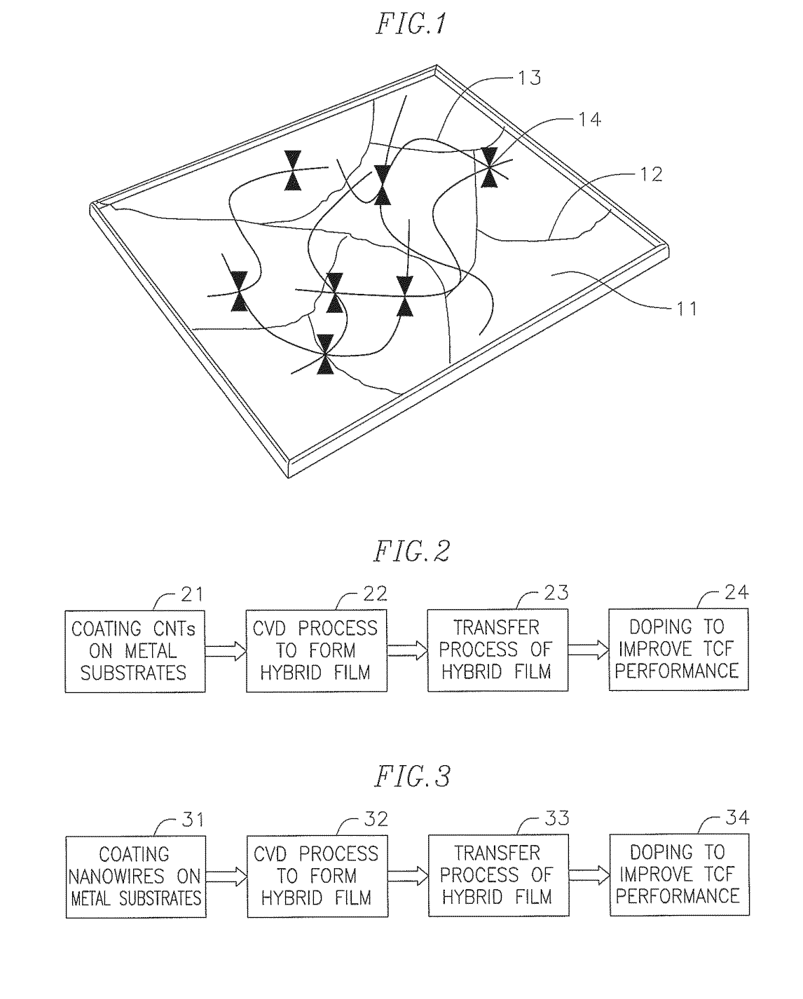

According to embodiments of the present invention, a transparent conductive film (TCF) includes a hybrid nanostructure-graphene film having improved performance, as compared to prior art TCFs. In some embodiments, the nanostructures may be one dimensional CNTs or nanowires, and the graphene may be two dimensional. Instead of simply stacking nanotubes, nanowires, or additional graphene sheets on an underlying graphene sheet, the hybrid structures according to embodiments of the present invention have a nanostructure-graphene hybrid structure in which the nanostructures and the graphene are integrally connected, thereby favoring electrical conduction. These integral connections are created as portions of the nanostructures (e.g., CNTs or nanowires) “melt” into a metallic substrate when exposed to the high temperature at which the graphene may nucleate and grow (as illustrated in FIG. 1). These melting sites act as nucleation sites for the graphene to grow between the nanostructures, and between the nanostructures and the substrate. Indeed, as used herein, the terms “integral connections,” “integral bonds,” “intrinsic connections,” “intrinsic bonds,” and like terms, refer to the bonding of the nanostructures to the graphene during this graphene deposition process which is performed in the presence of the nanostructures on the growth substrate, and does not refer only to simple van der Waals interactions between the nanostructures and the graphene.

Referring to FIG. 1, a graphene-based hybrid transparent conductive film, according to embodiments of the present invention, includes a plurality of graphene domains 11, a boundary 12 between the graphene domains, carbon nanostructures 13, and integral (e.g., chemical) bonds 14 between the nanostructures 12 and the graphene domains 11. The nanostructures, according to embodiments of the present invention, can include carbon nanotubes and/or carbon or metallic nanowires.

According to embodiments of the present invention, a process for preparing the graphene-based hybrid transparent conductive films includes coating the nanostructures on a metallic substrate, annealing the nanostructures at a graphene deposition temperature sufficient to partially melt the nanostructures into the substrate and produce nucleation sites between the nanostructures and the substrate, and depositing a graphene layer on the substrate and growing the graphene layer in the presence of the nanostructures in domains on the substrate around the nucleation sites to thereby form the graphene-based hybrid TCF film. In some embodiments, the annealing and deposition are carried out by a chemical vapor deposition (CVD) process.

As mentioned previously, the coated nanostructures can include CNTs or carbon or metal nanowires. In some embodiments of the present invention, for example, the graphene-based hybrid film can be a CNTs/graphene hybrid TCF structure. As also discussed previously, prior art processes simply coated CNTs on an already transferred CVD graphene surface, or co-deposited CNTs and chemically modified graphene onto the film. In contrast, embodiments of the present invention grow the graphene in the presence of the nanostructures, and form nucleation sites created by the nanostructures, thereby creating stronger, integral connections between the nanostructures and the grown graphene domains.

CNTs or graphene have been catalytically etched at a high temperature (for example, >600° C.) by metallic nanoparticles (such as Fe, Ni, Pt, Cu, and so on) in a hydrogen environment. This process involves carbon decomposing on the surface of metal, carbon atoms diffusing across the metal particles, and formation of methane (CH₄) on the other surface of the particles with hydrogen. On a metallic foil, solid carbon (deposited carbon layer, sugar, PMMA, and so on) can be a source for graphene deposition in a CVD process.

In embodiments of the present invention, the CNTs can be coated on a metallic substrate, for example, a Cu foil, a Ni foil, etc. Nonlimiting examples of other suitable metallic substrates may include silver, platinum, and gold. As illustrated in FIG. 2, a CNT layer is first coated (at 21) on a metallic substrate by any coating or printing process, such as screen printing, slot die coating, spin coating, ink-jet printing, gravure printing, flexo printing, etc. While long single-walled CNTs with good electrical conductivity are well suited for constructing the TCFs according to embodiments of the present invention, processing SWNTs of this type for uniform coating can be a challenge. According to embodiments of the present invention, metallic SWNTs measuring about 50 micron in length and about 1 to about 2 nm in outer diameter could be suitable for the process. HiPco SWNTs (from NanoIntergris) and SWNTs made by the floating catalyst chemical vapor deposition (FCCVD) method are also suitable sources of CNTs.

During the CVD process (at 22), the nanostructures are annealed. The nanostructures coated on the metallic substrate are annealed at the graphene deposition temperature (e.g., about 500° to about 1080° C.). During the annealing process, part of the nanotubes contacting the metal surface of the substrate will “melt” into the substrate due to the metal catalytic effect, and carbon atoms will diffuse into the metal. These diffused carbon atoms then act as a source for the nucleation and growth of graphene during the CVD process.

In the meantime, a carbon source (such as, for example, methane) is fed into the CVD furnace so as to deposit graphene on the surface of the metal substrate on which the nanostructures are deposited. As a result, intrinsic connections are produced between the exposed parts of the carbon nanotubes and the newly grown graphene. Low-pressure CVD is used to grow graphene, normally on Cu foil. Pre-treating the Cu foil (e.g., by annealing at 100° C. for about one hour) enhances the quality of the graphene grown during the CVD process. Other conditions of the CVD process can include, for example, a vacuum range of about 50 mTorr to about 1000 mTorr, a growth time of about 30 min to about 2 hours, a temperature of about 950° C. to about 1050° C. (depending on the melting point of the metal substrate). For example, in some embodiments using Cu foil as the metallic substrate, the growth temperature may be about 1050° C. H₂ (from about 10 vol % to about 15 vol %) may be used as a reducing agent.

After the CVD process, the hybrid film including intrinsic connections between the nanostructures and the graphene can be transferred (at 23) onto a target substrate (such as, e.g., glass, PET, PEN, etc.) using known transfer techniques.

In some embodiments of the present invention, the performance of the resulting hybrid TCF may be further improved by optionally doping (at 24) the resulting film. The hybrid film can be doped with any suitable dopant, and in some embodiments, the dopant can be selectively applied to a region of the hybrid film. In some embodiments, the dopant can be used to decrease the junction electrical resistance. Doping is known in the art, and typical dopants are disclosed, for example, in U.S. Patent Publication No. 2013/0137248 (filed on Sep. 26, 2012, and assigned to International Business Machines Corporation, Armonk, N.Y.), the entire content of which is incorporated herein by reference.

In some embodiments, the nanostructures can include either carbon nanostructures (such as nanotubes or nanowires), or metallic nanostructures (such as nanotubes or nanowires). The metallic nanostructures, such as metallic nanowires, can be any suitable metallic nanostructure, such as silver nanowires, Ni nanowires, Cu nanowires, Cu/Ni alloy nanowires, etc.

As mentioned previously, prior art processes have simply coated silver nanowires on an already transferred CVD graphene surface, or co-deposited silver nanowires and chemical-modified graphene to form a film. In contrast, embodiments of the present invention grow the graphene in the presence of the metallic nanostructures, and form nucleation sites created by the metallic nanostructures, thereby creating stronger, integral connections between the nanostructures and the grown graphene domains.

On the metallic substrate, the parts of metal nanowires contacting the substrate melt into the substrates and form localized alloyed surfaces at the high temperature used for graphene growth (e.g., about 500° C. to about 1080° C.). In embodiments of the present invention, the metallic nanowires are coated on a metallic substrate, for example, a Cu foil, a Ni foil, etc. Then, the nanowire-coated metallic substrate is annealed up to the graphene deposition temperature (e.g., about 500° to about 1080° C.). During annealing, part of the nanowires contacting the metal melts into the substrate, creating localized alloy sites that can act as nucleation sites for the growth of the graphene.

In the meantime, a carbon source (for example, CH₄) is fed into the CVD furnace to deposit graphene on the surface of the metal substrate, and also on the surface of metal nanowires on the substrate. As a result, intrinsic connections are formed between the exposed parts of the graphene-coated nanowires and the newly grown graphene. This process is illustrated in FIG. 3. In particular, a metal nanowire layer is first coated (at 31) on a metallic substrate by any coating and printing process, such as screen printing, slot die coating, spin coating, ink-jet printing, gravure printing, flexo printing, etc. Then, the CVD process (at 32) is performed, during which process, both the annealing and graphene deposition takes place. After the CVD process, the intrinsically hybridized film can be transferred (at 33) to a target substrate (such as, e.g., glass, PET, PEN, etc.), which is selected based on the desired TCF application. A further doping process (at 34) may optionally be performed to improve the TCF performance of the hybrid structure, as described previously.

### Example 1

This example tested the stability of a CNT film on a metal substrate after high temperature treatment.

A double-walled CNTs (DWNTs) film was first deposited by a floating catalyst CVD process on a substrate, and then a piece of the DWNT film was peeled from the substrate and coated on a cleaned Cu foil. The DWNT film was then densified by dropping acetone on it, and then dried. The DWNTs-coated Cu foil was put into a CVD furnace, the furnace was heated up to 1000° C. under hydrogen flow at a vacuum of 500 mTorr, and held in that state for 30 minutes. Methane was then fed in for another 30 minutes.

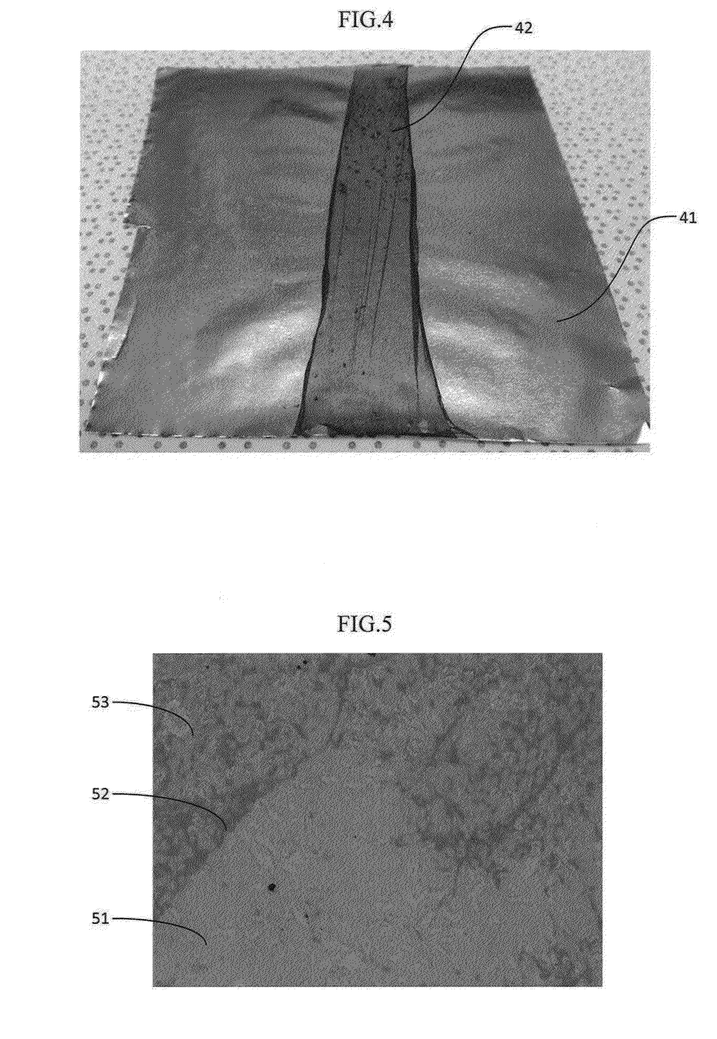

As shown in FIG. 4, the DWNT film survived the annealing process and the graphene CVD process at 1000° C. There was no apparent change in appearance before and after the CVD process. Referring more specifically to FIG. 4, the graphene-coated Cu surface is shown at 41. The CNT/graphene coated surface is shown at 42.

### Example 2

In this example, two CVD temperatures (1000° C. and 1050° C.) with different annealing times were performed on a DWNTs-coated Cu foil.

The process for the coating of the DWNTs and the CVD was similar to that in Example 1. At each CVD temperature of 1000° C. and 1050° C., two annealing durations were run: 30 minutes and 120 minutes. Following the annealing step, methane was fed for another 30 minutes for all the test runs. Graphene and DWNTs/graphene films were transferred to a PET substrate after removing the Cu substrates. For further doping to improve the TCF performance, the graphene and DWNTs/graphene films were immersed into an approximately 10M HNO₃ solution, and then washed in deionized water. Light transmittance and sheet resistance (Rs) were measured, and the results are shown in Table 2 below.

TABLE 2
TCF performance of hybrid DWNTs/graphene structure
synthesized at different temperatures and annealing times

| | | | | Rs Graphene |
|---|---|---|---|---|
| Annealing | Optical | | | before/ |
| temperature | transmittance | Rs after | Rs after | after HNO3 |
| and | (%) @ 550 nm | transfer | HNO3 | @ 97.3% T |
| duration | (w/o PET) | (Ω/▭) | (Ω/▭) | (Ω/▭) |
| 1000° C./30 min | 83.6% | 155 | 149 | — |
| 1000° C./120 min | 82.9% | 183 | 137 | — |
| 1050° C./30 min | 78.5% | 225 | 116 | 1675/668 |
| 1050° C./120 min | 79.3% | 215 | 142 | 1448/544 |

As shown in Table 2, the hybrid DWNTs/graphene TCFs show reasonable performance. However, the higher annealing and deposition temperatures did not yield better results, and the longer annealing time did not yield better results. Without being bound by any particular theory, a possible reason for this is that the higher annealing temperature and longer annealing time may damage more of the DWNTs.

### Example 3

This example compared the performance of the DWNTs, graphene, and DWNTs/graphene hybrid.

The process for DWNTs coating and CVD was similar to that in Example 1. The CVD temperature of 1000° C. was tested with an annealing duration of 60 minutes followed by methane exposure of another 30 minutes. The same DWNTs film was also transferred to the PET film for comparison. The same CVD conditions were used to grow graphene and DWNTs/graphene films, which were also transferred to PET substrates after removing the Cu substrates. For further improving the TCF performance, the DWNTs/PET film, graphene/PET film and DWNTs/graphene/PET films were immersed into an approximately 10M HNO₃ solution, and then washed in DI water. Light transmittance and sheet resistance (Rs) were measured, and the results are shown in Table 3 below.

TABLE 3
Comparison of TCF performance of DWNTs, graphene,
and DWNTs/graphene hybrid film on PET substrates

| | Optical transmittance | Rs after | Rs after |
|---|---|---|---|
| | (%) @ 550 nm | transfer | HNO3 |
| Samples | (w/o PET) | (Ω/▭) | (Ω/▭) |
| DWNTs/PET | 96% | 1816 | 778 |
| Graphene | 97% | 2634 | 1197 |
| DWNTs/Graphene | 94% | 1432 | 1083 |

As shown in Table 3, the hybrid DWNTs/graphene TCFs showed reasonable performance. In particular, the hybrid DWNTs/graphene films showed lower Rs compared with pure graphene and with DWNTs with compromised optical transmittance. The Rs value may be improved if no DWNTs aggregate (as shown in FIG. 5) after densification on the Cu foil before the CVD process. Referring to FIG. 5, a graphene monolayer is shown at 51. The boundary of the hybrid DWNTs/graphene structure and the graphene only structure is shown at 52. The area of the hybrid DWNTs/graphene structure is shown at 53.

### Example 4

This example compared the performance of DWNTs, graphene, and DWNTs/graphene hybrid with different graphene CVD temperatures, and hybridized DWNTs and graphene together to produce a TCF film with improved performance.

The process for DWNTs coating and CVD is similar to that in Example 1. Two CVD temperatures of 900° C. and 950° C. were tested with an annealing duration of 30 min, followed by methane exposure of another 30 min. The same DWNTs film was also transferred to a PET film for comparison. The same CVD conditions were used to grow graphene and DWNTs/graphene films, which were also transferred to PET substrates after removal from the Cu substrates. For further improving the TCF performance, the DWNTs/PET film, graphene/PET film and DWNTs/graphene/PET films were immersed into an approximately 10M HNO₃ solution, and then washed in deionized water. Light transmittance and sheet resistance (Rs) were measured, and the results are shown in Tables 4 and 5, below.

TABLE 4
Comparison of TCF performance of DWNTs,
graphene, and DWNTs/graphene hybrid
film on PET substrates with CVD temperature of 950° C.

| | Optical transmittance | Rs after | Rs after |
|---|---|---|---|
| | (%) @ 550 nm | transfer | HNO3 |
| Samples | (w/o PET) | (Ω/▭) | (Ω/▭) |
| DWNTs | 96% | 1816 | 778 |
| Graphene | 98% | 3041 | 920 |
| DWNTs/Graphene | 95.7% | 808 | 367 |

TABLE 5
Comparison of TCF performance of DWNTs,
graphene, and DWNTs/graphene hybrid
film on PET substrates with CVD temperature of 900° C.

| | Optical transmittance | Rs after | Rs after |
|---|---|---|---|
| | (%) @ 550 nm | transfer | HNO3 |
| Samples | (w/o PET) | (Ω/▭) | (Ω/▭) |
| DWNTs | 96% | 1816 | 778 |
| Graphene | 94.5% | 56 k | 81 k |
| DWNTs/Graphene | 94.9% | 521 | 325 |

As shown in Table 4 and Table 5, the hybrid DWNTs/graphene TCFs showed much lower Rs compared with pure graphene and DWNTs with reasonable compromised optical transmittance. A significant result is that the TCF performance improved as the CVD temperature lowered, even though graphene quality worsens at lower CVD temperatures. Indeed, the hybrid DWNTs/graphene TCF recorded the best performance, registering an Rs of 325Ω/□ at 94.9% visible light transmittance, which is better than a four-layer graphene TCF, which registers an Rs of 350Ω/□ at 90% light transmittance.

In summary, according to embodiments of the present invention, a process for making a graphene-based hybrid film includes applying a layer of electrically conductive nanostructures (such as CNTs or conductive nanowires) to a metallic substrate and subjecting the nanostructures to a temperature sufficient to partially melt the nanostructures into the substrate via an annealing process that produces nucleation sites between the nanostructures and the substrate. The process further includes introducing a carbon source at a temperature sufficient to deposit graphene on the substrate and the nanostructures, thereby growing the graphene in the presence of the nanostructures in domains on the substrate around the nucleation sites to form a hybrid film. The different graphene domains are electrically connected by the nanostructures, which bridge the graphene domains together in the film. The contact between the nanostructures and the graphene domains is in excess of van der Waals forces and includes integral bonds or connections (e.g., chemical bonds) that yield enhanced electrical conductivity and structural integrity to the resulting graphene-based hybrid film.

The processes according to embodiments of the present invention provide several improvements. For example, the process yields a film with improved electrical conductivity, and improved mechanical stability. The nanostructures reinforce the graphene film, which improves film transfer and provides stronger, more flexible and more stretchable films. Additionally, the process is cost-effective, providing cost efficiency as it only requires one transfer from the substrate since the nanostructures are coated on the same substrate on which the graphene is grown, and the graphene can be grown to whatever thickness is desired.

While certain embodiments of the present invention have been shown and described, those of ordinary skill in the art will understand that various modifications can be made to the described embodiments without departing from the spirit and scope of the described embodiments, as defined in the following claims.

What is claimed is:

1. A hybrid film, comprising:
a substrate;
nanostructures on the substrate;
graphene domains on the substrate and the nanostructures, the graphene domains being integrally connected to the nanostructures.

2. The hybrid film according to claim 1, wherein the nanostructures comprise carbon nanotubes or metallic nanowires.

3. A method of a making a hybrid film, the method comprising:
coating nanostructures on a metallic substrate;
annealing the nanostructures at a temperature sufficient to deposit graphene on the substrate to form nucleation sites at contact points between the nanostructures and the metallic substrate; and
depositing graphene on the metallic substrate and the nanostructures by growing graphene from the nucleation sites to form a hybrid nanostructures-graphene film.

4. The method according to claim 3, wherein the metallic substrate comprises a silver foil, a copper foil, a nickel foil, or a nickel-copper alloy foil.

5. The method according to claim 3, wherein the nanostructures comprise carbon nanotubes or metallic nanowires.

6. The method according to claim 3, wherein the temperature sufficient to deposit graphene is about 500° C. to about 1080° C.

7. The method according to claim 3, wherein the depositing the graphene comprises introducing a carbon source gas to the metallic substrate and the nanostructures, and maintaining the temperature sufficient to deposit graphene.

8. The method according to claim 3, further comprising transferring the hybrid nanostructures-graphene film from the metallic substrate to a separate substrate.

9. The method according to claim 8, further comprising doping the hybrid nanostructures-graphene film.

10. The method according to claim 9, wherein the doping comprises immersing the hybrid nanostructures-graphene film in an HNO₃ solution.

11. The method according to claim 3, wherein the annealing the nanostructures and the depositing the graphene are performed by chemical vapor deposition.
